(19) United States
(12) Patent Application Publication
(10) Pub. No.: US 2019/0043819 A1
(43) Pub. Date: Feb. 7, 2019

(54) ELECTRONIC PACKAGE HAVING REDISTRIBUTION STRUCTURE

(71) Applicant: Siliconware Precision Industries Co., Ltd., Taichung City (TW)

(72) Inventors: Chi-Ching Ho, Taichung City (TW); Ying-Chou Tsai, Taichung City (TW)

(21) Appl. No.: 15/869,249

(22) Filed: Jan. 12, 2018

(30) Foreign Application Priority Data
Aug. 2, 2017 (TW) 106126048

(51) Int. Cl. H01L 23/00; H01L 23/31; H01L 21/56

(52) U.S. Cl. CPC H01L 24/13; H01L 23/3128; H01L 23/3135; H01L 21/561; H01L 24/11; H01L 2924/20641; H01L 21/6835; H01L 2224/0231; H01L 2224/13024; H01L 2224/02379; H01L 24/16; H01L 2224/16227; H01L 2924/3512

(57) ABSTRACT

An electronic package is provided, including an electronic component, a redistribution structure formed on the electronic component, a plurality of conductive posts bonded to the redistribution structure, and a redistribution layer bonded to the conductive posts. As such, the electronic component that meets the requirement of miniaturization can be electrically connected to an electronic device through the redistribution structure, the conductive posts and the redistribution layer.

### BACKGROUND

### 1. Technical Field

The present disclosure relates to package structures, and, more particularly, to an electronic package that meets the requirement of miniaturization.

### 2. Description of Related Art

Along with the progress of electronic industries, electronic products are developed toward the trend of miniaturization and multi-function. Accordingly, various package types have been developed. To meet the demands of semiconductor devices for high integration, miniaturization and high electrical performance, flip-chip bonding technologies have been developed.

To achieve flip-chip bonding, a plurality of conductive bumps are formed on an active surface of a chip (or other semiconductor structures) for electrically connecting the active surface of the chip to an external electronic device or a packaging substrate. As such, the size of the package is greatly reduced.

FIGS. 1A and 1B are schematic cross-sectional views showing a method for fabricating a flip-chip semiconductor package 1 according to the prior art. Referring to FIGS. 1A and 1B, a semiconductor chip 11 is bonded to a packaging substrate 10 through a plurality of solder bumps 13. Then, an underfill 12 is formed between the semiconductor chip 11 and the packaging substrate 10 to encapsulate the solder bumps 13. Thereafter, a plurality of solder balls 14 are mounted to a lower side of the packaging substrate 10. As such, the packaging substrate 10 can be further mounted to a main board 9 of an electronic product through the solder balls 14.

In addition, following Moore's law, the semiconductor chip 11 is developed toward miniaturization and has fine-pitch circuits.

However, limited by the fabrication process, circuits of the packaging substrate 10 and the solder balls 14 on the packaging substrate 10 have their sizes that cannot be reduced to the same extent as the semiconductor chip according to Moore's law.

Further, the semiconductor chip 11 has a low structural strength due to its exposed lateral surface 11c. Therefore, when the flip-chip semiconductor package 1 is picked up and placed at a suitable position and subjected to an SMT (Surface Mount Technology) process, cracking may occur to the semiconductor chip 11, thus reducing the product yield.

Furthermore, since the packaging substrate 10 is usually an organic substrate or a core substrate, its fabrication process cannot produce circuits having a line width/pitch less than 130 μm.

Therefore, how to overcome the above-described drawbacks has become critical.

### SUMMARY

In view of the above-described drawbacks, the present disclosure provides an electronic package, which comprises: an electronic component having an active surface and a non-active surface opposite to the active surface; a redistribution structure formed on the active surface of the electronic component and electrically connected to the electronic component; a plurality of conductive posts bonded to and electrically connected to the redistribution structure; a redistribution layer bonded to and electrically connected to the conductive posts, wherein each of the conductive posts has one end connected to the redistribution structure and the other end connected to the redistribution layer; an encapsulating layer bonded to the electronic component; and a packaging layer bonded to the encapsulating layer.

The present disclosure provides another electronic package, which comprises: an electronic component having an active surface, a non-active surface opposite to the active surface, and a lateral surface adjacent to and connected to the active surface and the non-active surface; an encapsulating layer bonded to the lateral surface of the electronic component; a redistribution structure formed on the active surface of the electronic component and the encapsulating layer and electrically connected to the electronic component; a plurality of conductive posts bonded to and electrically connected to the redistribution structure; a redistribution layer bonded to and electrically connected to the conductive posts, wherein each of the conductive posts has one end connected to the redistribution structure and the other end connected to the redistribution layer; and a packaging layer formed on the redistribution layer and encapsulating the encapsulating layer, the redistribution structure and the conductive posts.

In an embodiment, the electronic package further includes a plurality of conductive elements bonded to the redistribution layer for an electronic device to be connected thereto. In another embodiment, the redistribution layer has a line pitch of at least 150 μm for bonding to the conductive elements.

In an embodiment, the redistribution structure has a circuit layer electrically connected to the electronic component and the conductive posts. In another embodiment, the circuit layer has a line pitch of at least 100 μm for bonding to the conductive posts.

In an embodiment, the encapsulating layer is further formed on the non-active surface of the electronic component.

In an embodiment, the packaging layer is further formed on the non-active surface of the electronic component.

In an embodiment, the non-active surface of the electronic component or a top surface of the encapsulating layer is exposed from an upper surface of the packaging layer.

According to the present disclosure, the electronic component that has fine-pitch circuits for meeting the requirement of miniaturization can be electrically connected to an electronic device through the fan-out redistribution structure and the fan-out redistribution layer.

Further, the encapsulating layer and the packaging layer enhance the structural strength of the electronic component so as to prevent the electronic component from being damaged during a subsequent SMT process or transportation of the electronic package and hence improve the product yield.

### BRIEF DESCRIPTION OF DRAWINGS

FIGS. 1A and 1B are schematic cross-sectional views showing a method for fabricating a flip-chip semiconductor package according to the prior art;

FIGS. 2A to 2H are schematic cross-sectional views showing a method for fabricating an electronic package according to the present disclosure;

FIGS. 3A to 3C are schematic cross-sectional views showing various embodiments of FIG. 2H; and

FIGS. 4A to 4C are schematic cross-sectional views showing an RDL process according to the present disclosure.

### DETAILED DESCRIPTION OF EMBODIMENTS

The following illustrative embodiments are provided to illustrate the disclosure of the present disclosure, these and other advantages and effects can be apparent to those in the art after reading this specification.

It should be noted that all the drawings are not intended to limit the present disclosure. Various modifications and variations can be made without departing from the spirit of the present disclosure. Further, terms such as “first”, “second”, “on”, “a” etc. are merely for illustrative purposes and should not be construed to limit the scope of the present disclosure.

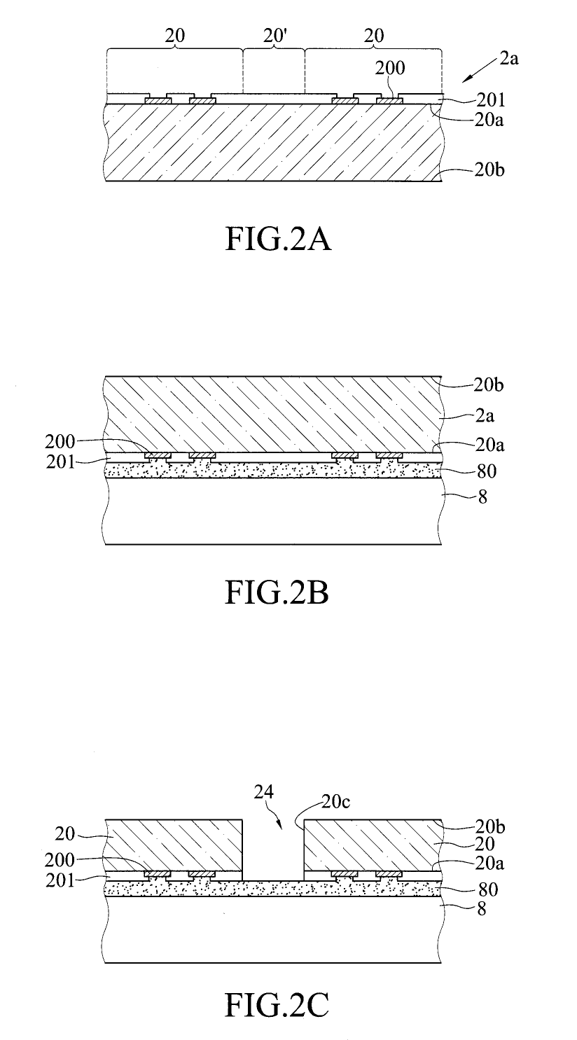

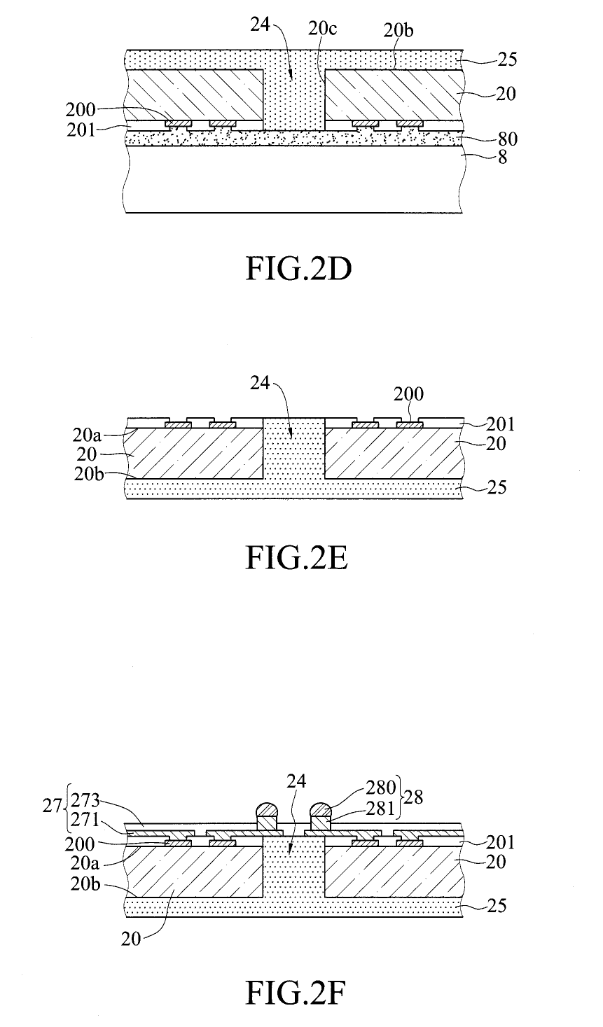

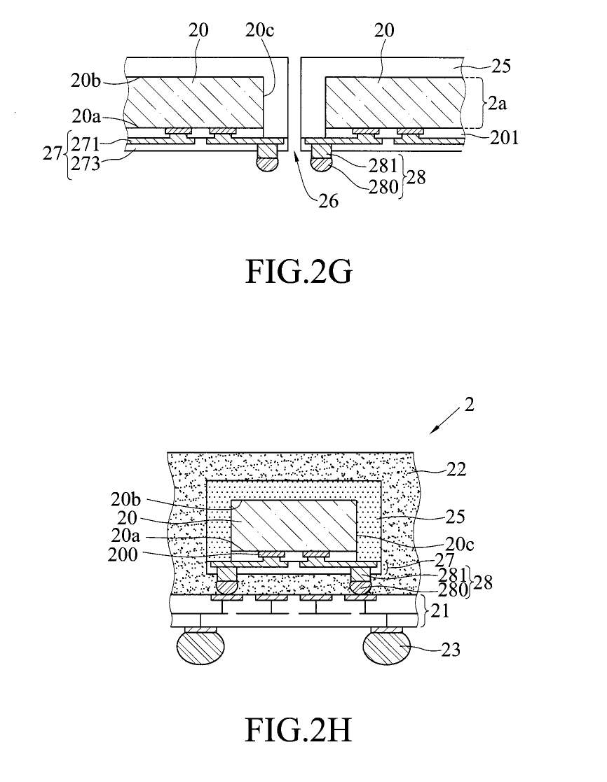

FIGS. 2A to 2H are schematic cross-sectional views showing a method for fabricating an electronic package 2 according to the present disclosure.

Referring to FIG. 2A, a full-panel substrate 2a is provided, which has a plurality of electronic components 20 and a plurality of isolating portions 20′ formed between adjacent ones of the electronic components 20.

In an embodiment, each of the electronic components 20 has an active surface 20a with a plurality of electrode pads 200 and a non-active surface 20b opposite to the active surface 20a. A passivation layer 201 is formed on the active surface 20a of the electronic components 20 and the electrode pads 200 are exposed from the passivation layer 201.

In an embodiment, each of the electronic components 20 is an active component, such as a semiconductor chip, a passive component, such as a resistor, a capacitor or an inductor, or a combination thereof. In an embodiment, the full-panel substrate 2a is a silicon wafer and the electronic components 20 are semiconductor chips.

Referring to FIG. 2B, a supporting member 8 is bonded to the passivation layer 201. In an embodiment, a release layer 80 is formed between the passivation layer 201 and the supporting member 8 to facilitate subsequent removal of the supporting member 8.

Referring to FIG. 2C, a plurality of grooves 24 are formed by cutting or etching the isolating portions 20′. As such, each of the electronic components 20 has a lateral surface 20c adjacent to and connected to the active surface 20a and the non-active surface 20b thereof.

In an embodiment, the isolating portions 20′ are completely removed to form the grooves 24. Optionally, the non-active surfaces 20b of the electronic components 20 can be thinned by grinding.

Referring to FIG. 2D, an encapsulating layer 25 is formed in the grooves 24 and on the electronic components 20 to cover the lateral surfaces 20c and the non-active surfaces 20b of the electronic components 20.

In an embodiment, the encapsulating layer 25 completely fills the grooves 24 and surrounds the lateral surfaces 20c of the electronic components 20. The encapsulating layer 25 is made of an insulating material, such as a curable liquid molding compound, a dry film, a photoresist material, or a solder mask layer.

Referring to FIG. 2E, the supporting member 8 and the release layer 80 are removed to expose the electrode pads 200, the passivation layer 201 and the encapsulating layer 25.

Referring to FIG. 2F, a redistribution layer (RDL) process is performed to form a fan-out redistribution structure 27 on the passivation layer 201 and the encapsulating layer 25. The redistribution structure 27 is electrically connected to the electrode pads 200. Then, a plurality of conductors 28 are formed on the redistribution structure 27.

In an embodiment, the redistribution structure 27 has a circuit layer 271 formed on the passivation layer 201 and electrically connected to the electrode pads 200, and an insulating layer 273 formed on the circuit layer 271. Further, a portion of the circuit layer 271 is exposed from the insulating layer 273 and the conductors 28 are formed on the exposed portion of the circuit layer 271 so as to be electrically connected to the circuit layer 271. The number of layers of the redistribution structure 27 can be designed according to the practical need. In an embodiment, at least one dielectric layer (not shown) is formed on the passivation layer 201 and the circuit layer 271, then a plurality of circuit layers are formed on the dielectric layer, and finally the insulating layer 273 is formed on the dielectric layer and the outermost circuit layer.

The circuit layer 271 has a line pitch of at least 100 μm for bonding to the conductors 28.

In an embodiment, each of the conductors 28 contains a conductive post 281, such as a copper post, and a conductive material 280, such as a solder material, formed on an end portion of the conductive post 281.

The melting point of the conductive post 281 is different from that of the conductive material 280. As such, the height of the conductive post 281 remains unchanged while the height of the conductive material 280 varies after a reflow process.

Specifically, since the average value and deviation of the size and height of the conventional solder bumps 13 are not easy to be controlled, the solder bumps 13 cannot meet a fine pitch requirement. In particular, if the average value of the size or height of the solder bumps 13 is quite small, the underfill process may be adversely affected and a popcorn phenomenon may occur. On the other hand, if the average value of the size or height of the solder bumps 13 is quite large, a solder bridge may occur, thus resulting in a short circuit. In addition, if the deviation of the size and height of the solder bumps 13 is large, defects may occur to the solder joints and thus lead to a poor electrical connection quality. Also, the solder bumps 13 arranged in a grid array may have poor coplanarity. Consequently, uneven stresses may be applied on the solder joints, thus causing damage of the semiconductor chip 11.

In contrast, the conductive posts 281 according to the present disclosure are made of copper or a material having a melting point higher than that of the solder material. Since the shape of the conductive posts 281 does not change during the reflow process, the height and size of the conductors 28 can be controlled so as to overcome the above-described drawbacks of the solder bumps 13 and meet the fine pitch requirement.

Referring to FIG. 2G, a singulation process is performed to cut the full-panel substrate 2a along cutting paths 26, thereby separating the electronic components 20 from one another.

In an embodiment, the cutting paths 26 correspond to the grooves 24, and are less in width than the corresponding grooves 24 so as to leave the encapsulating layer 25 on the lateral surfaces 20c of the electronic components 20.

Referring to FIG. 2H, the active surface 20a of the electronic component 20 is bonded to a redistribution layer 21 through a plurality of conductors 28. Then, a packaging layer 22 is formed on the redistribution layer 21 to encapsulate the encapsulating layer 25 and the conductors 28. The packaging layer 22 is in direct contact with lateral and bottom surfaces of the redistribution structure 27, the conductors 28, and the redistribution layer 21.

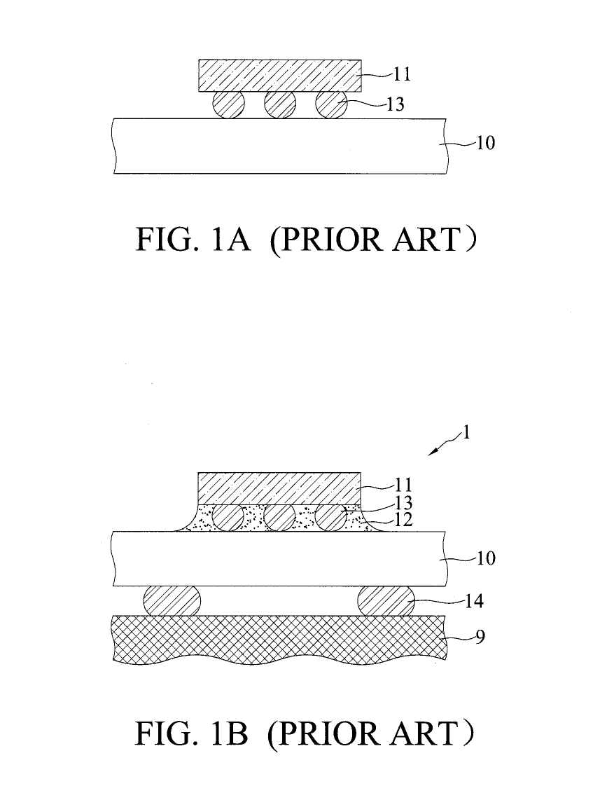

In an embodiment, the redistribution layer 21 is of a fan-out type, and has upper and lower sides for being bonded to and electrically connected to the conductors 28 and the conductive elements 23. As such, the redistribution layer 21 can be further connected through the conductive elements 23 to an electronic device, such as a circuit board (for example, the main board 9 of FIG. 1B). The redistribution layer 21 has a line pitch of at least 150 μm for bonding to the conductive elements 23.

The conductive elements 23 can contain solder bumps, copper posts and other appropriate structural aspects.

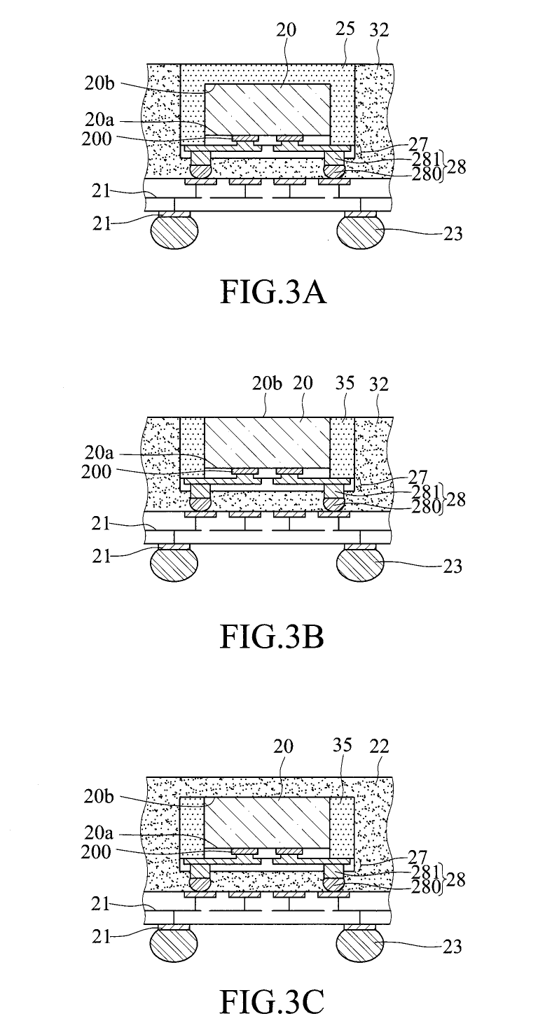

FIGS. 3A to 3C are schematic cross-sectional views showing various embodiments of FIG. 2H. In an embodiment, referring to FIG. 3A, the packaging layer 32 is partially removed to expose a top surface of the encapsulating layer 25. For example, the top surface of the encapsulating layer 25 is flush with an upper surface of the packaging layer 32. In another embodiment, referring to FIG. 3B, both the encapsulating layer 35 and the packaging layer 32 are partially removed to expose the non-active surface 20b of the electronic component 20. In an embodiment, the non-active surface 20b of the electronic component 20 is flush with the top surfaces of the encapsulating layer 35 and the packaging layer 32.

In a further embodiment, referring to FIG. 3C, the encapsulating layer 35 is partially removed to expose the non-active surface 20b of the electronic component 20. In an embodiment, the non-active surface 20b of the electronic component is flush with the top surface of the encapsulating layer 35. Then, the non-active surface 20b of the electronic component 20 and the top surface of the encapsulating layer 35 are encapsulated by the packaging layer 22. As such, the non-active surface 20b of the electronic component 20 is in contact with the packaging layer 22.

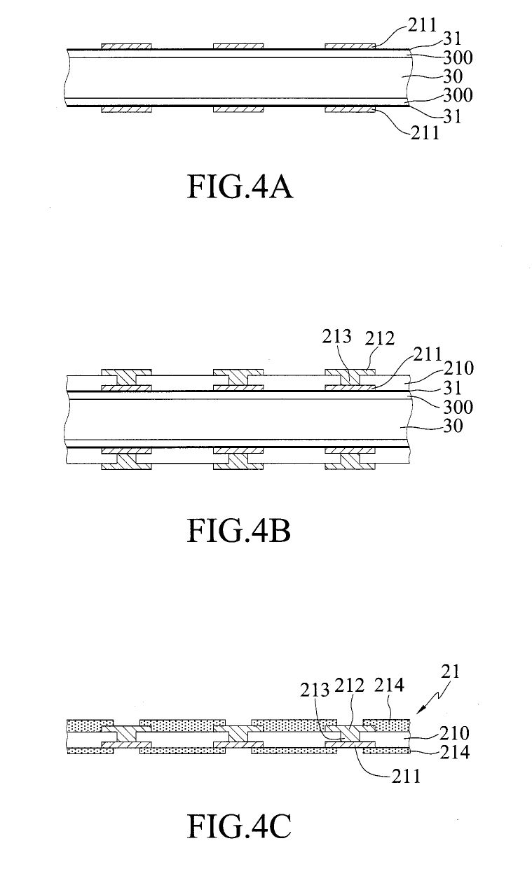

FIGS. 4A to 4C show a process for forming the redistribution layer 21. Referring to FIG. 4A, a first circuit layer 211 is formed on a conductive layer 31 on each side of a carrier 30 by electroplating. Then, referring to FIG. 4B, a dielectric layer 210 is laminated (or a passivation layer is formed) on the carrier 30 to cover the first circuit layer 211. Then, a second circuit layer 212 is formed on the dielectric layer 210 and a plurality of conductive vias 213 are formed in the dielectric layer 210 for electrically connecting the first circuit layer 211 and the second circuit layer 212. Subsequently, the circuit structures on both sides of the carrier 30 are separated from the carrier 30 through a release layer 300 and the conductive layer 31 is removed Finally, referring to FIG. 4C, a protection layer (or an insulating layer) 214 is formed on both sides of the dielectric layer 210 and portions of the first circuit layer 211 and the second circuit layer 212 are exposed from the insulating layer 214, thus obtaining the redistribution layer 21.

According to the present disclosure, the minimized electronic component 20 (i.e., the electronic component 20 meets the miniaturization requirement) can be electrically connected to an electronic device such as the main board 9 of FIG. 1B through the circuit layer 271 of the fan-out redistribution structure 27 and the fan-out redistribution layer 21.

Further, the encapsulating layer 25 and the packaging layer 22 enhance the structural strength of the electronic component 20 so as to prevent the electronic component 20 from being damaged during a subsequent SMT process or transportation of the electronic package 2 and hence improve the product yield.

The present disclosure further provides an electronic package 2, which has distribution layer 21, an electronic component 20, an encapsulating layer 25, 35, and a packaging layer 22, 32.

The distribution layer 21 is for bonding to a plurality of conductive elements 23.

The electronic component 20 has an active surface 20a, a non-active surface 20b opposite to the active surface 20a, and a lateral surface 20c adjacent to and connected to the active surface 20a and the non-active surface 20b.

The encapsulating layer 25, 35 is in direct contact with the lateral surface 20c of the electronic component 20.

A redistribution structure 27 is formed on the active surface 20a of the electronic component 20 and the encapsulating layer 25, 35 to allow the electronic component 20 to be bonded to the redistribution layer 21 through the redistribution structure 27 via the conductors 28.

The packaging layer 22, 32 is formed on the redistribution layer 21 to encapsulate the encapsulating layer 25, 35, the redistribution structure 27 and the conductors 28.

In an embodiment, the redistribution layer 21 is connected to an electronic device through the conductive elements 23, and the redistribution layer 21 has a line pitch of at least 150 μm for bonding with the conductive elements 23.

In an embodiment, the redistribution structure 27 has a circuit layer 271 electrically connected to the electronic component 20, and the circuit layer 271 has a line pitch of at least 100 μm for bonding with the conductors 28.

In an embodiment, the encapsulating layer 25, 35 is in direct contact with the redistribution structure 27.

In an embodiment, the encapsulating layer 25 is further formed on the non-active surface 20b of the electronic component 20.

In an embodiment, the packaging layer 22 is further formed on the non-active surface 20b of the electronic component 20.

In an embodiment, the packaging layer 22, 32 is in direct contact with the encapsulating layer 25, 25.

According to the present disclosure, the electronic component that has fine-pitch circuits for meeting the requirement of miniaturization can be electrically connected to an electronic device through the fan-out redistribution structure and the fan-out redistribution layer.

Further, the encapsulating layer and the packaging layer enhance the structural strength of the electronic component so as to prevent the electronic component from being damaged and hence improve the product yield.

The above-described descriptions of the detailed embodiments are only to illustrate the preferred implementation according to the present disclosure, and it is not to limit the scope of the present disclosure. Accordingly, all modifications and variations completed by those with ordinary skill in the art should fall within the scope of present disclosure defined by the appended claims

1. An electronic package, comprising:
an electronic component having an active surface and a non-active surface opposite to the active surface;
a redistribution structure formed on the active surface of the electronic component and electrically connected to the electronic component;
a plurality of conductive posts bonded to and electrically connected to the redistribution structure;
a redistribution layer bonded to and electrically connected to the conductive posts, wherein each of the conductive posts has one end connected to the redistribution structure and the other end connected to the redistribution layer;
an encapsulating layer bonded to the electronic component and formed on the non-active surface of the electronic component and
a packaging layer bonded to the encapsulating layer, wherein a top surface of the encapsulating layer is exposed from an upper surface of the packaging layer.

2-3. (canceled)

4. The electronic package of claim 1, wherein the packaging layer is in direct contact with the encapsulating layer.

5. The electronic package of claim 1, wherein the packaging layer is further formed on the redistribution layer to encapsulate the encapsulating layer.

6-7. (canceled)

8. The electronic package of claim 1, wherein the electronic component has a lateral surface adjacent to and connected with the active surface and the non-active surface.

9. The electronic package of claim 8, wherein the encapsulating layer is bonded to the lateral surface of the electronic component.

10. The electronic package of claim 9, wherein the encapsulating layer is in contact with the lateral surface of the electronic component.

11. The electronic package of claim 9, wherein the encapsulating layer is in direct contact with the redistribution structure.

12. The electronic package of claim 11, wherein the redistribution structure is further formed on the encapsulating layer.

13. The electronic package of claim 9, wherein the packaging layer is formed on the redistribution layer and encapsulates the encapsulating layer, the redistribution structure and the conductive posts.

14-16. (canceled)

17. The electronic package of claim 1, further comprising a plurality of conductive elements bonded to the redistribution layer for an electronic device to be connected thereto.

18. The electronic package of claim 17, wherein the redistribution layer has a line pitch of at least 150 μm for bonding to the conductive elements.

19. The electronic package of claim 1, wherein the redistribution structure has a circuit layer electrically connected to the electronic component and bonded to the conductive posts.

20. The electronic package of claim 19, wherein the circuit layer has a line pitch of at least 100 μm for bonding to the conductive posts.
